(19) United States
(12) Patent Application Publication
(10) Pub. No.: US 2007/0227881 A1
(43) Pub. Date: Oct. 4, 2007

(54) ROTARY VACUUM FEEDTHROUGH FOR ROTATABLE MAGNETRONS

(75) Inventors: Harald Gaertner, Schoeneck (DE); Andreas Sauer, Grossostheim (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials GmbH & Co. KG, Alzenau (DE)

(21) Appl. No.: 11/692,710

(22) Filed: Mar. 28, 2007

(30) Foreign Application Priority Data
Mar. 29, 2006 (EP) 06111910.3

(51) Int. Cl. C23C 14/00

(52) U.S. Cl. 204/298.2

(57) ABSTRACT

The present invention concerns a cathode arrangement, preferably for a magnetron cathode, especially for operation in the case of medium-to-high frequency alternating voltage or currents with a rotatable cathode, of which at least one part is arranged rotatably and vacuum-tight in at least one fixed component, and an insert, which is provided between the rotatable part and fixed component(s), with the insert made from an isolator.

### PRIORITY

This application claims priority under 35 U.S.C. §119(a) to EP 06111910.3, filed Mar. 29, 2006, the entire disclosure of which is incorporated herein by reference for all purposes.

### BACKGROUND OF THE INVENTION

Rotatable magnetrons or generally rotatable cathodes or targets for coating by means of sputtering are well-known. In the case of such rotatable cathodes and magnetrons (rotatable magnetrons), a cylindrical cathode or a corresponding target is rotated during the sputtering process, with the magnet arrangement arranged inside the cylindrical cathode or target. An example of this is given in US 2002/0189939 A1, the entire disclosure of which is incorporated herein by reference.

Since such coating processes and sputtering processes proceed under vacuum, devices and arrangements must be made available that facilitate the feedthrough of a rotatable shaft through a vacuum chamber wall under maintenance of the vacuum conditions in the vacuum chamber. Such rotary vacuum feedthroughs have, in accordance with the prior art, for example US 2002/0189939, the entire disclosure of which is incorporated herein by reference, so-called ferro-fluid seals in which a colloidal suspension of ultramicroscopic particles is accommodated in a liquid carrier and held by a magnet arrangement in a gap to be sealed.

Additionally, simple O-rings are also used as seals, as is described for example in U.S. Pat. No. 6,365,010 B1, the entire disclosure of which is incorporated herein by reference for all purposes, with, however, in accordance with the prior art, ferro-fluid seals being preferable.

From U.S. Pat. No. 5,518,592, the entire disclosure of which is incorporated herein by reference for all purposes, a rotary vacuum feedthrough is additionally known, in which an external and an internal sleeve of a rotary vacuum feedthrough are arranged spaced apart from each other and accommodate between them bearing and sealing means.

Although quite good experiences have been obtained in some cases with these seals, it has transpired that especially when such rotatable cathodes are operated in the medium-to-high frequency range with alternating voltages or currents, continuous operation of the installations cannot be ensured, since failure of the seals is to be observed especially at high output.

### SUMMARY OF THE INVENTION

It is therefore the object of the present invention to overcome the disadvantages of the prior art and, especially for use at high-to-medium frequency alternating voltages or currents with high output, to make available a cathode arrangement with a rotatable cathode, with which continuous operation is ensured. Furthermore, the arrangement shall be simple to install, rugged and economical.

This object is achieved by means of a cathode arrangement having the characteristics of claim 1. Advantageous embodiments are the object of the dependent claims.

The present invention starts out from the realization of the inventors that the inadequate service life of the seals in cathode arrangements operated at medium-to-high frequency alternating voltages and currents is related to the fact that, in the case of ferro-fluid seals, coupling of the medium-to-high frequency electromagnetic waves into the ferro-fluid seals occurs and thus eddy currents are induced, which heat the seal. The same applies to seals, which are arranged for example in metallic inserts. In addition, precisely in the case of ferro-fluid seals, small potential differences at the gaps, at which the ferro-fluid liquid is provided, give rise to field strengths that can lead to arc discharges and thus to destruction of the seal. Accordingly, the inventors have recognized that it is essential to make available a rotary vacuum feedthrough which essentially forgoes electrically conductive and especially metallic components. Thus, in accordance with the invention, an insert is provided between a rotatable part of a rotatable cathode or target and one or more surrounding fixed components, said insert implemented as insulator and consisting especially of a polymer that is suitable for vacuum use. Especially suitable in this regard are polyetheretherketones (PEEK), polyoxymethylene or polyacetal (POM) or polyethylene terephthalate (PET). The use of an insulator as insert between the rotatable part of the magnetron cathode and the accommodating or surrounding fixed components avoids the coupling of eddy currents and thus a protected arrangement of seals by the insert is possible.

The insert can be arranged both rotationally fixed at the rotatable part of the cathode or rotationally fixed at the surrounding fixed component(s), such that the insert is either itself stationary or rotates with the rotatable cathodes.

The insert can be formed in one or more parts and has in principle an essentially cylindrical-tubular shape, such that the rotatable part of the cathode, especially a corresponding drive shaft or the like, is surrounded by the insert. Additionally, the insert can preferably at one end, for example the end assigned to the vacuum chamber, have a flange-like beginning, such that this, relative to the fixed component(s), such as a vacuum chamber wall or a housing wall of a drive unit for the rotatable drive of the rotatable cathode, has contact and sealing surfaces not only parallel to the axis of rotation of the rotatable part, but also transversely to it and especially perpendicularly to it. This has the advantage that corresponding seals in the contact and sealing surfaces can act not only in the radial direction but also in the axial direction, a fact which greatly facilitates installation of the insert and moreover prevents damage of the seals during installation.

Preferably, a counter sliding surface is assigned facing the insert, said counter sliding surface provided facing the inside of the insert. Insert and counter sliding surface rotate relative to each other when the cathode rotates. However, either the insert can be held stationary or the counter sliding surface. Especially, insert and counter sliding surface have at least one sealing and sliding surface mutually contacting each other, to which corresponding seals are also provided.

The counter sliding surface can be designed as a separate component or be integrated into the rotatable part, thus for example the drive shaft, or into the surrounding fixed component(s), such as a housing wall.

The sliding and/or sealing surfaces of the counter sliding surface are preferably adapted to the insert and/or seals arranged between them, such that optimal sliding and sealing can be obtained, without the occurrence of unwanted abrasion.

Between the counter sliding surface and the insert are arranged preferably one or more dynamic seals, which provide a sealing effect during the relative rotary motion of insert and counter sliding surface. Dynamic sealing thus means that sealing occurs here under a relative motion while static sealing is said to occur when the components to be mutually sealed do not move against each other.

The insert preferably has one or more dynamic seals on one of its main sides, i.e. for example at its interior, whereas at the opposite main side, for example at the exterior, it has one or more static seals or these are assigned to it. Of course, the arrangement of the seals may also be reversed, such that the dynamic seals are provided at the exterior, while the static seals are at the interior. In this case, for example, the insert would be connected rotationally fixed to the shaft, such that, at the interior, the static seals seal the shaft while the insert rotates relative to the surrounding, fixed components or a counter sliding surface arranged at them and thus the dynamic seals are arranged at the exterior surface or are assigned to this.

Preferably, at the side at which the dynamic seals are provided, the insert has at least one, preferably several circumferential channels, especially provided between the seals, wherein the channels serve to suction the spaces and/or to introduce lubricants, which contribute to better sliding of the dynamic seals.

In so far as a counter sliding surface is provided as a separate component, this component has, at the side opposite the insert, one or more static seals or is assigned to this side in order that sealing of a corresponding adjacent component may be obtained.

Altogether, the seals, that is, both the static seals and the dynamic seals, can act on sealing surfaces that are aligned parallel to the axis of rotation or transversely, especially perpendicularly to the axis of rotation, such that the seals act in the radial and/or axial direction. Especially in the case of the static seals between a fixed insert or a counter sliding surface on one hand and the surrounding fixed components on the other, it can be advantageous, to provide static seals in an axial effective direction, since these facilitate installation and enable the seals to be treated gently during installation.

Especially, it can be advantageous, to provide the insert, which has an essentially cylindrical-tubular basic shape, with a flange-like beginning and extension, such that sealing surfaces develop in the axial direction in order to accommodate axially effective seals there. This facilitates, for example, particularly simple installation of the insert, including from the vacuum chamber side.

The dynamic and static seals which can be provided comprise O-rings, X-rings, sealing lip bodies of all shapes as well as other sealing bodies which are especially annular.

The seals are preferably arranged in grooves or groove-like recesses, which, can be provided in encircling manner both at the insert, at the counter sliding surfaces assigned to the insert, to the surrounding fixed component(s) and/or the rotatable parts. Preferably, however, the seals are provided in the insulating insert.

The seals and especially the dynamic seals are formed from polytetrafluoroethylene (Teflon), rubber, other elastomers or composite materials with graphite or carbon fibre or comprise these and preferably have sliding coatings. The counter sliding surface and especially its surface are preferably formed from hardened steel, diamond-like carbon layers, chrome oxide layers or other sliding layers.

With the described cathode arrangement and the rotary vacuum feedthrough, a vacuum-tight arrangement of rotatable cathodes and targets and especially magnetrons under maintenance of good vacuum conditions is possible in a simple manner, wherein good service life is ensured simultaneously for medium-to-high frequency use in the case of alternating voltages or alternating currents with high output.

### BRIEF DESCRIPTION OF DRAWINGS

Further advantages, characteristics and features of the present invention are apparent from the following detailed description of preferred embodiments using the enclosed drawings. The drawings show in purely schematic form in:

FIG. 1 a cross-sectional view of a drive unit for a rotatable magnetron cathode;

FIG. 2 a cross-sectional view of a rotary vacuum feedthrough in accordance with the invention;

FIG. 3 a further cross-sectional view of a second embodiment of a rotary vacuum feedthrough;

FIG. 4 a cross-sectional view of a third embodiment of a rotary vacuum feedthrough;

FIG. 5 a cross-sectional view of a fourth embodiment of a rotary vacuum feedthrough; and in FIG. 6 a partial cross-sectional view of a drive unit for a magnetron rotatable cathode with a fifth embodiment of the rotary vacuum feedthrough.

### DETAILED DESCRIPTION OF THE INVENTION

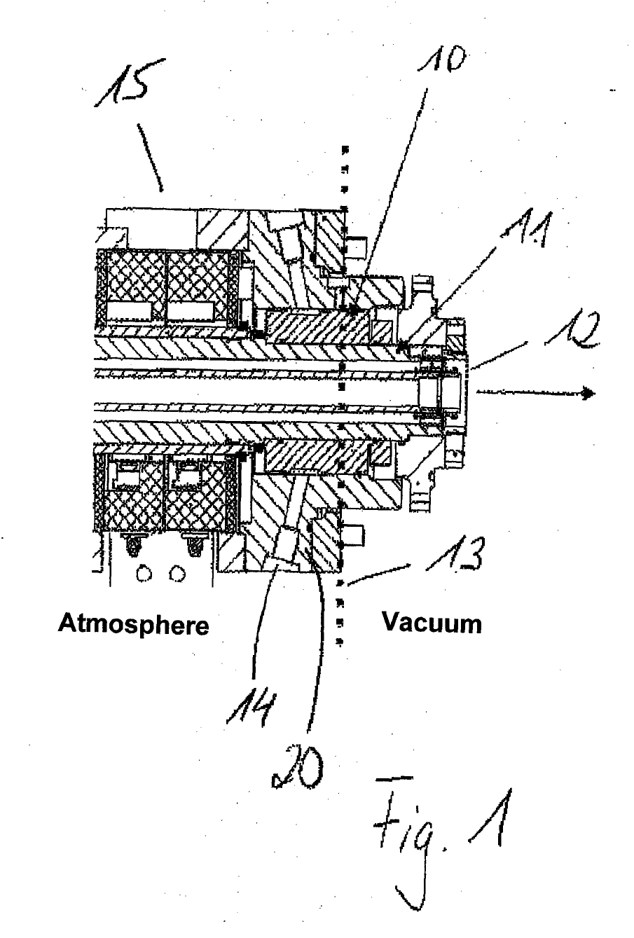

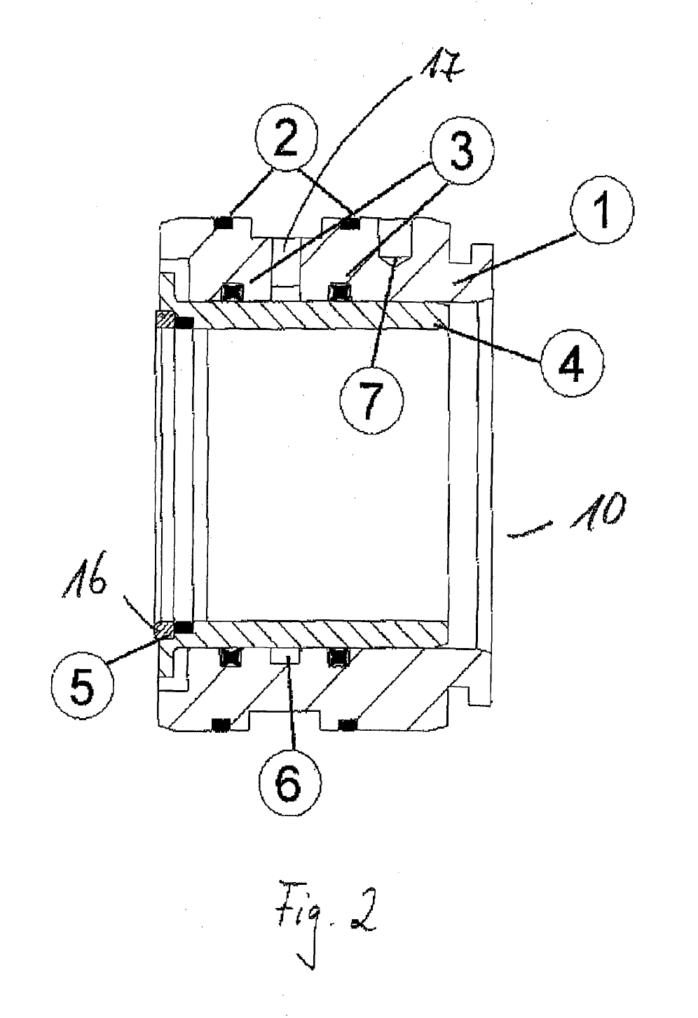

FIG. 1 shows a drive unit 15 for a rotatable magnetron. The rotary drive accommodates a rotatable shaft 11, at whose end a flange 12 is provided for the arrangement of a rotatable cathode or a target. With 13, a dotted line indicates schematically the shape of a vacuum chamber wall in which the drive unit 15 can be installed vacuum-tight.

The drive unit 15 has a rotary vacuum feedthrough 10 for the shaft 11, which is described in more detail in the following figures.

In the cross-sectional view of FIG. 1, suction lines 14 are provided above and below the rotatable shaft 11, said lines opening into the rotary vacuum feedthrough where, as will be shown later, they act together with the rotary vacuum feedthrough 10 together for the purposes of suction. Several of these suction lines 14 can be provided spaced apart from each other around the cylindrical periphery of the drive unit 15 or the rotary vacuum feedthrough 10.

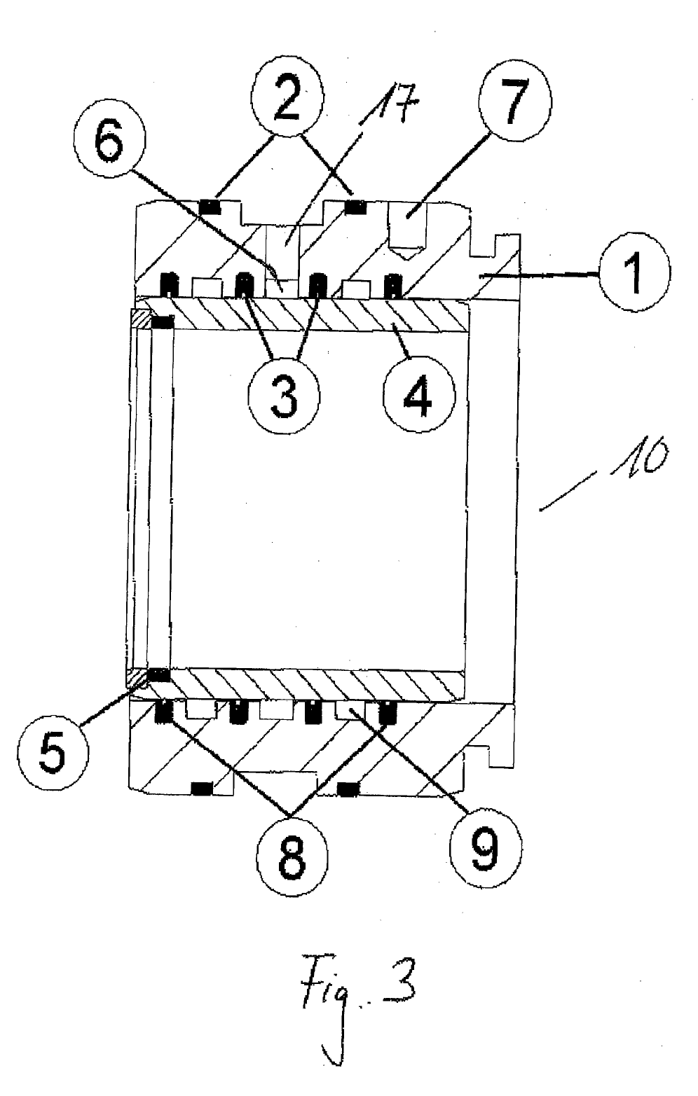

FIG. 2 is a cross-sectional view of a first embodiment of a rotary vacuum feedthrough 10, which has an essentially cylindrical-tubular insert 1 of a polymer material that is especially suitable for vacuum conditions. Suitable polymers are those from the group comprising polyetheretherketone (PEEK), polyoxymethylene or polyacetal (POM) and polyethylene terephthalate (PET), which have good sliding properties, low abrasion, stability to chemicals and the like.

In accordance with the embodiment shown, the insert 1 is mounted to the housing of the drive unit 15 or directly to a vacuum chamber wall (not shown) with a bolt connection, which engages with the blind hole 7. Thus, insert 1 is kept stationary, with, in the radial direction, two static seals 2 seal in the form of O-rings sealing a sealing surface of the fixed component in the form of the housing of the drive unit 15 or the vacuum chamber wall. The rings 2 are accommodated here in grooves of the insert 1.

On the inside of the cylindrical-tubular insert 1, two circumferential grooves are likewise provided, in which dynamic seals 3 are accommodated in the form of X-rings. These seal a likewise cylindrical-tubular body, or its sealing surface, which represents the counter sliding surface 4. The counter sliding surface 4 in the embodiment of FIG. 2 is a separate component, which is arranged on the shaft 11 or in a recess of the shaft 11. For example, this can be effected by shrinking. Between the counter sliding surface 4 and the shaft 11 (not shown) is provided a static seal 5, which in the embodiment shown in FIG. 2 is held by a tension ring 16 in a recess or shoulder at one end of the counter sliding surface 4. At the inside of the insert 1, a channel 6 can be formed by providing a further circumferential groove, said channel connected by means of a feedthrough 17 to the suction line 14 and serves to monitor the two dynamic seals 3. Changing the pressure, which is set with a backing pump whose suction power is lower than the pumps of the process chamber, makes it possible to determine which of the seals 3 is defective. With increasing pressure, the seal loses its effect towards the atmosphere side, while at low pressure, the seal loses its effect toward the process chamber.

From the embodiment shown of the rotary vacuum feedthrough 10, it is clear that, through the shape of the insert 1 made from an insulating polymer, an insulating rotary vacuum feedthrough is created, since metallic components can be dispensed with to the extent that no through-going metallic connection is created. In addition, the induction of eddy currents in the insert 1 is avoided.

Additionally, the provision of the counter sliding surface makes it possible to adjust the sliding and/or sealing surfaces between insert 1 and counter sliding surface 4 or the dynamic seals 3 and the counter sliding surface 4. The counter sliding surface 4 is manufactured, especially at its exterior, that is, the sealing and/or sliding surface, from hardened steel, and/or provided with a diamond-like carbon layer (DLC) or a chrome oxide layer.

The dynamic sliding seals in the form of the X-rings can, for example, be rings of Viton or NBR, with or without sliding coating.

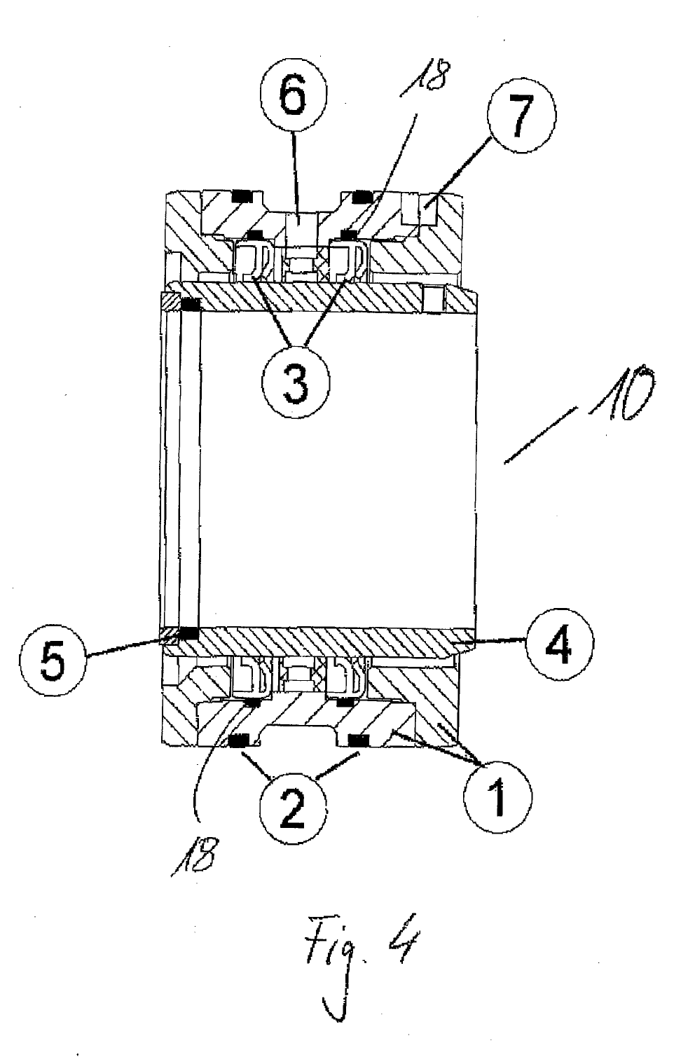

FIG. 3 likewise shows a cross-sectional view of a further embodiment of a rotary vacuum feedthrough 10, which corresponds in its basic structure to the embodiment of FIG. 2. Accordingly similar or identical components are provided with identical reference numerals.

Apart from a slight design change concerning the counter sliding surface (no flange-like end, left side of picture), the embodiment of FIG. 3 differs essentially in the fact that more dynamic seals 3 are provided, and that other sealing elements are used.

In the embodiment of FIG. 3, a total of four dynamic sealing rings made from polytetrafluoroethylene material (PTFE) are provided, with this material capable of being a composite material, for example, of PTFE with graphite or carbon fibre.

Additionally to the circumferential channel 6, two further circumferential groove-like recesses 9 are provided, which serve to accommodate lubricants in the regions between the dynamic seals 3. As lubricants, especially vacuum-suited lubricants can be used here, which serve the sliding properties of the rotation seals 3, which are arranged between the recesses 9 or adjacent to these, and the suction channel 6.

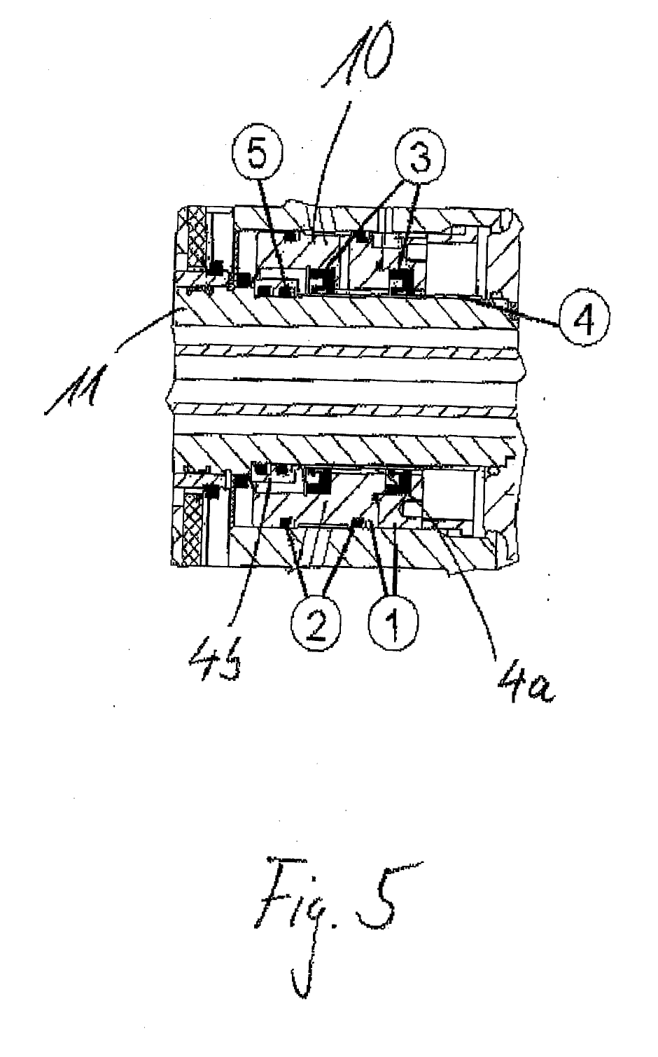

FIG. 4 shows a third embodiment of a rotary vacuum feedthrough in accordance with the invention, in which the insert 1 is formed in two pieces. The two-piece form of the insert has the advantage that the dynamic sealing elements 3 can be easily inserted in the form of sealing lip bodies of PTFE or PTFE composite materials into the corresponding accommodation spaces, with the basic shape of the insert 1 in the form of a cylindrical-tubular form being maintained further by the complementary parts of the insert 1. However, for the formation of suitable sealing surfaces between the sealing lip bodies 3 and the insert 1, additional sealing elements 18 are provided at the insert 1. In all other respects, the embodiment of FIG. 4 essentially corresponds to the embodiments of FIGS. 2 and 3.

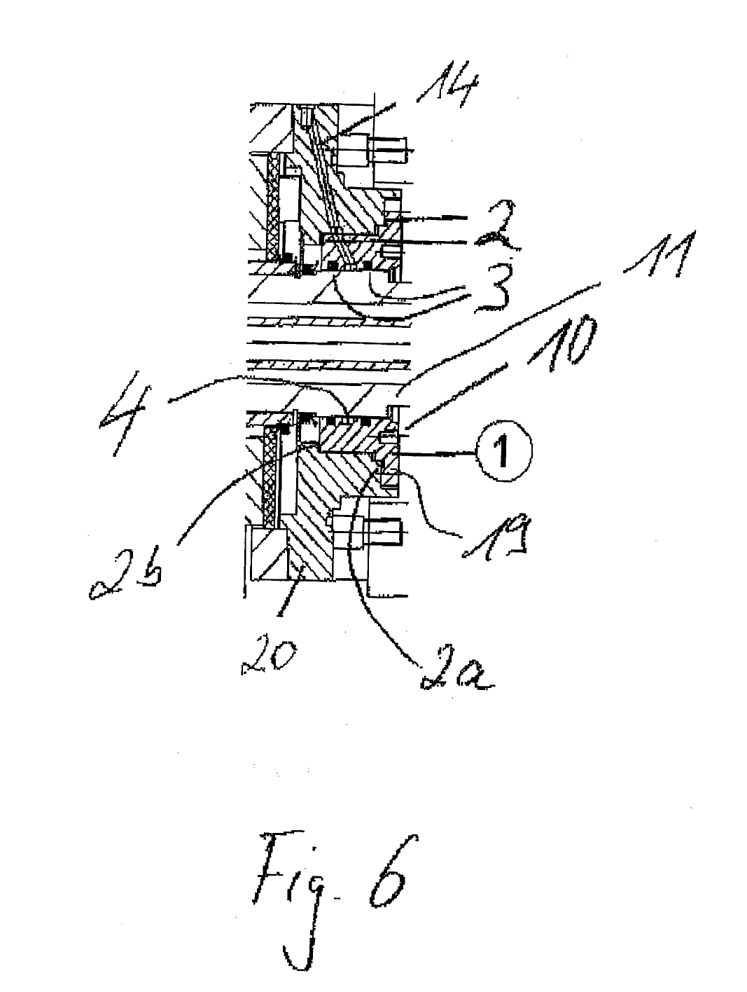

A further embodiment of a rotary vacuum feedthrough 10 is shown in the cross-sectional view of FIG. 5. In this embodiment, a two-piece insert is again provided, which has two static seals 2 at its exterior, for example in the form of O-rings, which seal a housing or the like.

Additionally, another counter sliding surface 4 in the form of an essentially cylindrical-tubular body is provided, which has two regions, more precisely a thin sliding surface region and a thicker sealing region 4b, in which, in the embodiment shown, two static seals 5 for sealing between the counter sliding surface 4 and the shaft 11 are provided.

As in the examples of FIGS. 2 to 4, the counter sliding surface 4 with the shaft 11 rotates, while the insulating insert 1 is held stationary and seals radially outward with the static seals 2.

Between the counter sliding surface 4, especially the sliding region 4a and the insert 1, circumferential sealing bodies 3 are again provided, which are accommodated in the corresponding recesses or grooves of the insert 1. These dynamic seals 3 differ in their shape from the embodiments described previously. As may be seen in FIG. 5, essentially annular sealing bodies 3 are used in the embodiment of FIG. 5, which have an essentially L-shaped cross-section.

Like the preceding sealing elements 3, these bodies can also be formed from rubber, e.g. Viton, from PTFE, or a comparable material with or without sliding coatings.

FIG. 6 shows a further embodiment of a rotatable cathode arrangement in accordance with the invention with a corresponding rotary vacuum feedthrough 10. In this arrangement, the insert 1 has an essentially cylindrical-tubular shape with a flange extension 19, that makes it possible to arrange a first static seal 2a for the housing 20 not in the radially effective direction but in the axially effective direction, i.e. the sealing surface is not parallel to the axis of rotation of the shaft 11, but essentially arranged transversely, especially perpendicularly to it. This makes possible an especially simple installation of the insert 1 preferably also from inside the vacuum chamber, without fear of damage to the static seals 2.

A second static seal 2b, likewise in the axially effective direction, i.e. in a sealing surface arranged perpendicularly to the axis of rotation, is provided at the face of the insert 1. Additionally, the embodiment of FIG. 6 shows that the counter sliding surface 4 can be provided integrally in the shaft 11, without the necessity for forming a separate component. The dynamic seals 3, which can be formed in accordance with each of the aforementioned methods, thus seal directly relative to the shaft 11.

In the embodiments of FIGS. 1 to 6, the rotary vacuum feedthrough 10 is constructed in such a way in each case that the insert 1 is arranged rotationally fixed in the housing 20 of a drive unit 15 or a vacuum chamber wall, while the counter sliding surface 4 with the rotatable shaft 11 rotates or is integrated into this. Of course, however, it is also conceivable for the insert 1 to be arranged rotationally fixed at the shaft 11 and thus to rotate with this, while the counter sliding surface 4 is arranged stationary in the housing 20 or the vacuum chamber wall. Additionally, it is also conceivable for the counter sliding surface 4 to be integrated in the housing 20 or in the vacuum chamber wall.

Additionally, in the embodiments shown, both the seals 2 and the dynamic seals 3 were accommodated in each case in groove-like recesses of the insert 1. It is, however, also conceivable for the seals 2, 3 to be accommodated in groove-like recesses of the counter sliding surface 4, the housing 20 or another fixed component like the vacuum chamber wall, or the shaft 11.

1. Cathode arrangement with a rotatable cathode comprising:
at least a rotatable part and at least a fixed component, the rotatable part being arranged rotatably and vacuum-tight in said fixed component; and
an insert provided between said rotatable part and said fixed component, wherein:
said insert has an essentially cylindrical-tubular shape, such that said rotatable part is surrounded by said insert;
said insert is manufactured from an insulator;
a counter sliding surface is assigned to the said insert, said counter sliding surface rotating relative to said insert on rotation of said cathode; and
the insert and counter sliding surface have at least a mutual sealing and sliding surface at which at least one dynamic seal is provided.

2. Cathode arrangement in accordance with claim 1, wherein the insert is manufactured from at least one of the group consisting of a polymer, a vacuum-suitable polymer, polyetheretherketone (PEEK), polyoxymethylene (POM), polyacetal and polyethylene terephthalate (PET).

3. Cathode arrangement in accordance with claim 1, wherein the insert is arranged rotationally fixed at one of the rotatable part and the fixed component.

4. Cathode arrangement in accordance with claim 1, wherein the insert is provided with a flange-like appendage at one of its ends.

5. Cathode arrangement in accordance with claim 1, wherein the insert is multipart.

6. Cathode arrangement in accordance with claim 1, wherein the counter sliding surface and the insert and seals with their sliding and sealing surfaces arranged between them are adapted to each other, such that optimum sliding and sealing are obtained.

7. Cathode arrangement in accordance with claim 1, wherein said counter sliding surface is provided as a separate component.

8. Cathode arrangement in accordance with claim 1, wherein said counter sliding surface is integrated into one of said rotatable part and said fixed component.

9. Cathode arrangement in accordance with claim 1, wherein at least one static seal is provided on the side of the insert opposite said counter sliding surface.

10. Cathode arrangement in accordance with claim 1, wherein at the side, at which dynamic seals are provided, said insert has at least one circumferential channel for at least one of suction and introducing lubricant.

11. Cathode arrangement in accordance with claim 1, wherein a side of said insert facing said fixed component extends at least partly in a radial direction.

12. Cathode arrangement in accordance with claim 1, wherein said counter sliding surface is formed as a separate component, to whose side opposite said insert at least one static seal is assigned.

13. Cathode arrangement in accordance with claim 1, wherein seals are provided, which act on sealing surfaces running at least one of parallel and transverse to said sealing surfaces.

14. Cathode arrangement in accordance with claim 1, wherein static seals between insert and fixed component are provided at sealing surfaces running transverse to a rotation axis.

15. Cathode arrangement in accordance with claim 1, wherein dynamic and static seals are provided, being at least one of a group consisting of O-rings, X-rings and sealing lip bodies.

16. Cathode arrangement in accordance with claim 1, wherein seals are provided, which are accommodated in grooves of at least one of said insert, of said counter sliding surface, of said fixed component and of said rotatable part.

17. Cathode arrangement in accordance with claim 1, wherein seals are provided, which comprise at least one of a group consisting of polytetrafluoroethylene (Teflon), graphite, carbon fiber, rubber elastomers with sliding coatings, elastomers without sliding coatings and combinations thereof.

18. Cathode arrangement in accordance with claim 1, wherein a sliding surface of said counter sliding surface comprises at least one of a group consisting of hardened steel, diamond-like carbon layers and chrome oxide layers.
